(19) United States
(12) Patent Application Publication
(10) Pub. No.: US 2009/0261065 A1
(43) Pub. Date: Oct. 22, 2009

(54) COMPONENTS FOR USE IN A PLASMA CHAMBER HAVING REDUCED PARTICLE GENERATION AND METHOD OF MAKING

(75) Inventors: HARMEET SINGH, Fremont, CA (US); John Daugherty, Fremont, CA (US); Vahid Vahedi, Oakland, CA (US); Hong Shih, Santa Clara, CA (US)

Correspondence Address: BUCHANAN, INGERSOLL & ROONEY PC, POST OFFICE BOX 1404, ALEXANDRIA, VA, 22313-1404, US

(73) Assignee: Lam Research Corporation, Fremont, CA (US)

(21) Appl. No.: 12/425,639

(22) Filed: Apr. 17, 2009

Related U.S. Application Data
(60) Provisional application No. 61/071,271, filed on Apr. 18, 2008.

(51) Int. Cl. H01L 21/306; B44C 1/22; C23F 1/00

(52) U.S. Cl. 216/53; 428/141; 156/345.1; 216/108

(57) ABSTRACT

Components entirely of ceramic with etched surfaces wherein the etched surface has a surface roughness value or at least about 100 microinches (about 2.54 microns) Ra, and methods of forming such.

### CROSS REFERENCE TO RELATED APPLICATION

This application claims priority under 35 U.S.C. §119(e) to U.S. Provisional Application No. 61/071,271, filed on Apr. 18, 2008, the entire content of which is incorporated herein by reference.

### BACKGROUND

Plasma processing apparatuses are used to process semiconductor substrates by techniques including etching, physical vapor deposition (PVD), chemical vapor deposition (CVD), ion implantation, and ashing or resist removal. One type of plasma processing apparatus includes a radio frequency (RF) capacitively coupled plasma reactor. RF capacitively coupled plasma reactors may be used for etch processes where plasma is formed in a gap between two electrodes, where one of the electrodes is an RF powered electrode and the other electrode is grounded.

In the field of plasma processing, the use of various materials with roughened surfaces are disclosed in the following references, the entire content of each is incorporated herein by reference. For instance, U.S. Pat. No. 6,723,437 discloses a process of treating semiconductor processing components of ceramic and non-ceramic materials such as silicon, silicon carbide, silicon nitride, diamond, yttria, zirconia, aluminum nitride, aluminum oxide and quartz by strong acid cleaning and CO2 bead blasting. U.S. Patent Publication 2002/0018921 discloses preparation of alumina substrates prior to plasma coating by sand blasting and ultrasonic cleaning. U.S. Pat. No. 5,762,748 discloses parts for vacuum chambers which have been chemically cleaned, bead blasted to roughen the surface and ultrasonic cleaned. Commonly assigned U.S. Pat. No. 5,916,454 discloses a method of roughening plasma chamber parts by bead blasting or chemical etching. U.S. Patent Publication 2003/0215643 discloses a method of roughening zirconia-based ceramic plasma chamber parts by hydrofluoric acid etching, grinding or sand blasting. U.S. Pat. No. 6,645,585 discloses a method of roughening a yttria-alumina plasma chamber by blasting with abrasive grains followed by sintering. U.S. Patent Publication No. 2006/0086458 discloses a method of roughening a ceramic liner of a plasma chamber to achieve a surface roughness of 100 to 180 micro-inches.

### SUMMARY

Provided is a component for use in a plasma chamber comprising a component entirely of a ceramic material. The component has a surface roughness value of at least about 100 microinches (about 2.54 microns) Ra and is produced by mechanical roughening and acid etching. The ceramic material can be yttria, zirconia and/or cerium oxide, which provide a longer RF life than quartz and/or silicon components.

In a preferred embodiment, the method of forming the component having a rough surface comprises successive material removal. First, the component is formed via sintering or hot pressing. The solid component is then roughened via percussion blasting and/or grinding. Finally, the roughened solid component is etched using a wet chemical etchant to form a component having a surface roughness value of greater than about 100 microinches (about 2.54 microns) Rₐ.

In a further embodiment, a method of forming a component for use in a plasma chamber via successive material removal comprises: forming a component entirely from yttria, zirconia, and/or cerium oxide; exposing the component to one or more of percussive blasting and surface grinding to form a roughened exposed surface on the component; and etching the roughened surface with a wet chemical etchant to remove loose fractured material and form a component having an etched surface, wherein the etched surface has a surface roughness value or at least about 100 microinches (about 2.54 microns) Ra.

In a yet further embodiment a method of forming a component with an etched surface comprises etching with hydrochloric acid the surface of a sintered component formed entirely of yttria to create an etched surface, wherein the etched surface has a surface roughness value or at least about 100 microinches (about 2.54 microns) Rₐ.

### BRIEF DESCRIPTION OF THE DRAWINGS

FIG. 1 is an illustration of a yttria edge ring entirely of yttria having a surface roughness value of about 64 microinches Rₐ after 200 RF hours of operation in a plasma etch chamber.

FIGS. 2-4 are SEM micrographs showing particles caused by conversion of yttria material into particulate matter during aggressive plasma bombardment of a yttria edge ring having a surface roughness value of about 64 microinches Rₐ after 200 RF hours of operation in a plasma etch chamber.

FIG. 5 is an energy dispersive x-ray (EDX) chemical spectrum showing that the particles of FIGS. 2-4 are formed by conversion of yttria to YF₃ particles during intense ion and chemical attack from the plasma of a yttria edge ring having a surface roughness value of about 64 microinches Rₐ after 200 RF hours of operation in a plasma etch chamber.

FIG. 6 is a cross-sectional view of an edge ring having a rough surface.

FIG. 7 is an illustration of an edge ring having a rough surface and a rectangular cross-section.

FIG. 8 is an illustration of an edge ring having a rough surface and at least one flange.

FIGS. 9A, 9B, 9C and 9D are illustrations of two-piece edge rings having a rough surface and having at least an inner piece and an outer piece in various configurations.

FIG. 10 is an illustration of an etch chamber containing exemplary embodiments of components.

### DETAILED DESCRIPTION

As the size of semiconductor substrates increases, improvements are needed in plasma processing chamber designs to address process uniformity requirements and address issues concerning consumable parts used in the chambers. For instance, as wafer size increases it is more difficult to achieve uniform etching across the wafer, especially for difficult to etch dielectric materials such as doped or undoped silicon oxide, e.g., silicon dioxide, fluorinated silicon oxide (FSG), boron phosphate silicate glass (BPSG), phosphate silicate glass (PSG), tetraethylorthosilicate (TEOS) deposited silicon oxide, organic and inorganic low-k materials, and the like. For etching such wafer materials it may be necessary to increase power levels supplied to electrodes which energize process gas into a plasma state with the result that consumable parts need replacement more frequently and etch rate uniformity across the wafer can be adversely affected.

The material used to construct, for example, an edge ring for the plasma processing of semiconductor wafers is necessarily consumable because of the aggressive physical and chemical attack by ions and chemically active free-radicals. Rapid consumption of the materials that directly bound the plasma device often dominate the cost of operation of the plasma chamber. Typically, consumable components, such as edge rings, are made of quartz (conductor etch) or quartz and silicon (dielectric etch). These materials are used because they form volatile etch products, such that the aggressive physical and chemical attack of the parts leads to removal of the material's constituents from the chamber as a gas, rather than the attack causing particle formation and other micro-contamination problems. However, a side effect of using quartz or quartz and silicon is that the lifetime of such parts is short; in some cases only about 200 hours of exposure to plasma conditions (RF hours). The short lifetime dominates the scheduled downtime of the device, which in turn greatly limits device availability. Also, if the consumable part is expensive, the short lifetime leads to high costs.

Those skilled in the art will appreciate that that the materials, surface characteristics and methods used to form edge rings can also be applied to other components for use in plasma chambers. Such exemplary components include, without limitation, gas injectors, confinement rings, upper electrodes, insulator rings and the like. These components can be made of the materials disclosed herein and can have a roughened surface as disclosed herein. Therefore, such components are considered to be within the scope of this disclosure.

The various consumable parts of a plasma chamber wear at different rates. The wear rate depends on the local ion bombardment energy, which can range from <30 eV to >1000 eV depending on the part location and use of the plasma chamber. It is most difficult to form an edge ring with a long lifetime. The edge ring surrounds the electrostatic chuck and bounds the wafer, which by design receives very high energy ion bombardment of >1000 eV. Thus, because of the close proximity to the wafer, the edge ring also can receive very high energy ion bombardment of >1000 eV.

The replacement of consumable materials and associated mean time between cleanings (MTBC) for plasma chambers is application specific. Currently, the MTBC for high aspect ratio contact applications (HARC) using the 2300 Exelan™ plasma chamber, manufactured by Lam Research Corporation, the assignee of the present application, is dictated by replacement of a quartz edge ring at about 200 RF hours of operation in a plasma etch chamber.

In plasma processing apparatuses, the MTBC can be used to determine how many plasma processing cycles may be run before a chamber should be opened and taken out of production. As such, in order to extend the MTBC, components made entirely of ZrO₂, Y₂O₃, yttria stabilized zirconia or CeO₂ are provided. In a preferred embodiment, the components are provided with a roughened surface to enhance adhesion of micro-contaminants during plasma processing.

Because of the wear rate of various components for use in plasma processing made of quartz or quartz and silicon, especially edge rings, the components could be formed of ceramics, either common or exotic, such as zirconia (ZrO₂), yttria (Y₂O₃), yttria stabilized zirconia, or other rare-earth materials, such as cerium oxide (CeO₂), which do not etch as quickly as quartz. Additionally, the components could be formed of carbides or nitrides, such as SiC, Si₃N₄, BN or B₄C, which may etch at lower rates than quartz and silicon.

Table 1 is a comparison of flexural strength and fracture toughness of ZrO₂, Y₂O₃, SiC, Si₃N₄, sapphire and AlN.

TABLE 1

| | ZrO₂ | Y₂O₃ | Si₃N₄ | SiC | Sapphire | AlN |
|---|---|---|---|---|---|---|
| Flexural Strength, | 2000 | 90 | 676 | 539 | 686 | 310 |
| (MPa at RT) | | | | | | |
| Fracture | 7.5 | 1.4 | 5.7 | 5.6 | 5.7 | N/A |
| Toughness, | | | | | | |
| (MPa√m) | | | | | | |
| Thermal | 9.6 | 9.1 | 2.6 | 4.0 | 4.5-5.3 | 4.8 |
| Expansion | | | | | | |
| Coefficient | | | | | | |
| (×10⁻⁶/° C.) | | | | | | |
| Thermal | 6.0 | 14.0 | 20-30 | 60-70 | 42 | 150 |
| Conductivity, | | | | | | |
| (at RT in W/m · K) | | | | | | |

As shown in Table 1, zirconia has a high mechanical strength. In addition, zirconia has good chemical stability. Thus, zirconia is a preferred material for the formation of components used in plasma processing devices. Other preferred materials include cerium oxide and yttria.

Yttria is an exotic ceramic that can be formed by various common ceramic processing techniques, such as sintering or hot pressing. Yttria does not form volatile products with common plasma chemistry and has a low etch rate and thus a potentially long lifetime.

Yttria, ceria, and zirconia may have non-stoichiometric compounds with or without additional elements or compounds contained therein.

In an embodiment, the components can be formed of zirconia sintered with yttria. In other embodiments, the components can be formed entirely of yttria, cerium oxide or zirconia. Such components, preferably have a life of at least about 250 RF hours (e.g., at least about 300 RF hours or at least about 400 RF hours). More preferably, the life components formed of zirconia, yttria and/or cerium oxide, is at least about 500 RF hours (e.g., 500 RF hours to about 600 RF hours, 600 RF hours to about 700 RF hours, 700 RF hours to about 800 RF hours, about 800 RF hours to about 900 RF hours or about 900 RF hours to about 1000 RF hours).

In a preferred embodiment, the components, such as edge rings, are made entirely of yttria, which is relatively inert to fluorine containing gases used in plasma etching and has a high dielectric constant. Compared to quartz, yttria has several advantages. First, yttria has a higher sputter threshold energy than quartz, and therefore is more sputter resistant. Also, yttria has a higher dielectric constant, on the order of 11, while quartz has a dielectric constant of about 3.5, which allows a thinner ring of yttria to be used and attain desired coupling of RF between the ground extension and the plasma. Accordingly, the use of a component made entirely of yttria can considerably improve the coupling of RF to a ground extension covered by the yttria ring, compared to the use of quartz rings. Improved coupling of RF to the ground extension improves plasma confinement in the gap between upper and lower RF electrodes used to energize process gas into a plasma state and increases the etch rate at the edge of the wafer. This increase in the etch rate at the edge of the wafer can improve the critical dimension and etch rate uniformity across the wafer.

Also, due to a lower reactivity in general, a component may also be used with various process gases, which may not be compatible with or unduly attack a quartz components. For example, exemplary process gases in a plasma processing apparatus that includes a yttria edge ring may include Ar, O₂, and fluorocarbons, such as C₄F₈, C₃F₆ and CHF₃ for etching materials such as silicon oxide. Thus, the yttria edge ring does not erode like quartz or quartz and silicon, resulting in a potentially longer RF life.

However, like other non-volatile-producing materials, a side effect of yttria is the production of particle micro-contamination, especially when yttria is used as a component material subject to high energy ion bombardment. Thus, in a preferred embodiment, the yttria component has a surface roughness value (Rₐ), which is sufficient to promote the adhesion of contaminants to the surface. The contaminants can include polymer deposits, which result from the use of polymer forming species (usually fluorocarbons) during plasma etching processes, such as metal etching processes.

By increasing the surface roughness value of a yttria component, the actual surface area of the yttria component is increased. Likewise, the yttria component provides potentially better adhesion of contaminants to the surface of the yttria component and less micro contamination of substrates during processing. Better adhesion of contaminants results in a longer life due to a longer time period before the “crust” of contaminants, which forms on the edge ring, peels off resulting in micro-contamination. Likewise, components formed entirely of zirconia or cerium oxide having a roughened surface also provide potentially better adhesion of contaminants.

The surface roughness value (Rₐ) represents the arithmetic average of the absolute values of the measured profile height deviations measured from the graphical center line of a surface. The graphical center line is a line about which roughness is measured and is a line parallel to the general direction of the profile (i.e. contour of the surface in a plane generally perpendicular to the surface) within the limits of the sampling length, such that the sums of the areas contained between it and those parts of the profile which lie on either side are equal.

In a preferred embodiment, the component having a rough surface is formed by successive material removal. Successive material removal includes multiple roughening steps, which are necessary to achieve sufficient roughening of the component surface.

First, the component is formed of yttria, zirconia, cerium oxide or combinations thereof via sintering or hot pressing. In an embodiment, the component can then be roughened by percussive blasting with a hard media. For example, the rough surface can be formed via bead blasting or grit blasting.

Grit blasting is a process whereby abrasive particles are accelerated and forcefully directed against the surface of the component. The high speed abrasive particles remove contaminants and also roughen the surface of the component. If grit blasting is employed, the level of roughness may be controlled by the size of the grit used, the force of grit impact and the duration of blasting.

Bead blasting is a process whereby beads are blown in a high speed gas stream onto the surface of the component. If bead blasting is employed, the level of roughness may be controlled by the size of the beads used, the force of bead impact and the duration of blasting. Typically, bead blasting yields a high level of uniformity.

In another embodiment, a rough surface can also be formed on a component via grinding with a coarse media or slurry. Suitable coarse media includes, without limitation, alumina, silicon carbide, cerium oxide, zirconia, diamond and combinations thereof. The slurry can include a suitably abrasive material including, for example, alumina, silicon carbide, cerium oxide, zirconia, diamond and combinations thereof. Preferably, the coarse media is chosen to have a particle size that produces the desired degree of surface roughness on the plasma exposed surface of the component.

In an embodiment, the grinding of the solid component can be accomplished using a grinding wheel with an appropriate roughness grade number and grinding the surface to a desired finish (e.g., greater than about 100 μ-inches Rₐ or greater than about 300 μ-inches Rₐ) using another wheel.

Because yttria, in particular, is brittle, during percussive blasting and/or grinding, the yttria breaks and fractures resulting in loose debris, which is a potential source of micro-contamination during plasma processing of substrates. Accordingly, it is desirable to reduce the number of attached particles to a suitably low count prior to the processing of substrates with the component present in the plasma reactor. Thus, after percussive blasting and/or grinding, it is necessary to clean surface fractures that were formed during the blasting and/or grinding via etching with a wet chemical etchant.

Accordingly, the chemical etch step removes contaminant particles from the treated component surfaces. The concentration, temperature, and pH of the etching liquid, the etching time, and other parameters of the etching process can be selected to achieve the desired surface morphology. Additionally, the mineral acid used in the etching step can be chosen to be cost efficient.

The preferred etching liquid is of semiconductor compatible purity and is formed using HCl, H₂SO₄, HNO₃ and/or other mineral acids (exclusive of HF). The concentration of the etching liquid is dependent on the acid chosen and the concentration necessary to remove particles, while maintaining the desired surface roughness.

For example, an etching liquid comprising sulfuric acid (H₂SO₄) and water having an acid concentration of about 5 wt % to about 96 wt % (e.g., about 5 wt % to about 15 wt %, about 15 wt % to about 25 wt %, about 25 wt % to about 35 wt %, about 35 wt % to about 45 wt %, about 45 wt % to about 55 wt %, about 55 wt % to about 65 wt %, about 65 wt % to about 75 wt %, about 75 wt % to about 85 wt % or about 85 wt % to about 96 wt %) can be used. The temperature of the solution ranges from room temperature to about 150° C. or up to the boiling temperature of more dilute solutions, for example a temperature between room temperature and 50° C. Concentrated sulfuric acid solutions boil at very high temperatures, so it can be impractical to boil concentrated acid for the etching step.

Also for example, an etching liquid comprising hydrochloric acid and water and having an acid concentration of about 5 wt % to about 35 wt % can be used (e.g., about 5 wt % to about 10 wt %, about 10 wt % to about 15 wt %, about 15 wt % to about 20 wt %, about 20 wt % to about 25 wt %, about 25 wt % to about 30 wt % or about 30 wt % to about 35 wt %). The temperature of the solution ranges from room temperature to about 100° C., for example a temperature between room temperature and 50° C.

Likewise, an etching liquid comprising nitric acid (HNO₃) and water, having an acid concentration of about 5 wt % to about 69 wt % can be used (e.g., about 5 wt % to about 10 wt %, about 10 wt % to about 15 wt %, about 15 wt % to about 20 wt %, about 20 wt % to about 25 wt %, about 25 wt % to about 30 wt %, about 30 wt % to about 35 wt %, about 35 wt % to about 40 wt %, about 40 wt % to about 45 wt %, about 45 wt % to about 50 wt %, about 50 wt % to about 55 wt %, about 55 wt % to about 60 wt %, about 60 wt % to about 65 wt % or about 65 wt % to about 69 wt %). The temperature of the solution can range from room temperature to about 120° C., or boiling (whichever is higher), for example a temperature between room temperature and 50° C.

It should be noted that acid boiling temperatures are a function of concentration, particularly for H₂SO₄. Also, different acid types have different boiling temperatures, which limits the maximum process temperatures for HCl and HNO₃ to lower temps than for H₂SO₄. Preferably, the etching is conducted under atmospheric pressure.

Preferred etching conditions include about 10 wt % H₂SO₄ at about 50° C. for about 6 hours; about 20 wt % H₂SO₄ at about 20° C. for about 48 hours; about 10 wt % HCl at about 50° C. for about 6-8 hours; and about 10 wt % HNO₃ at 50° C. for 7 hours.

Preferably, the etched component having a rough surface is essentially damage-free and fracture-free. Also, by changing the surface morphology of the component by etching, the actual surface area of the component is changed. The nominal surface area of the component is determined by its physical dimensions. The actual surface area of the component additionally takes into account the surface roughness. By increasing the surface roughness of the component, the actual surface area of the component also increases.

The successive material removal process can be used to achieve the same surface finish across the entire surface of the component or a different surface finish at different locations across the surface.

With the combination of blasting and/or grinding followed by etching, the surface roughness of the component can be made rougher than by mechanical roughening alone, while being nearly fracture free. Also, by using successive material removal, there is a lessened risk of contamination because particles loosened during blasting and/or grinding are removed during the etching process.

In order to try to minimize the contamination of semiconductor materials processed in apparatuses incorporating one or more components comprising yttria-containing materials as described herein, it is desirable that the yttria-containing materials be as pure as possible, e.g., include minimal amounts of potentially contaminating elements, such as transition metals, alkali metals, and the like. For instance, the yttria edge ring can be sufficiently pure to avoid on-wafer contamination of 10¹⁰ atoms/cm² or higher, preferably 10⁵ atoms/cm² or higher. Yttria edge rings preferably include over 50 wt % yttria, more preferably over 90 wt % yttria, and most preferably over 98 wt % yttria. Additionally, the yttria edge ring preferably contains less than 1000 ppm, or more preferably less than 500 ppm, of impurities such as silicon, aluminum, calcium, iron and/or zirconium. For example, one preferred yttria edge ring includes 99% or more yttria with a density greater than 4.5 g/cm³, preferably a density greater than 4.75 g/cm³.

One suitable Y₂O₃ material is available from Custom Technical Ceramics, Inc. located in Arada, Colo., USA, the material being 99.9% pure yttrium oxide with impurities of 20 ppm La₂O₃, 10 ppm Pr₆O₁₁, 8 ppm Nd₂O₃ less than 50 ppm other rare earth oxides, 40 ppm Si, 30 ppm Ca, 18 mm Fe, <1 ppm Cu, 3 ppm Ni, <1 ppm mg, 2 ppm Pd, the material being provided in bulk forms.

Likewise, it is also important that other ceramics, such as zirconia and cerium oxide are also as pure as possible to avoid contamination. For instance, the zirconia or cerium oxide components as formed can be sufficiently pure to avoid on-wafer contamination of 10¹⁰ atoms/cm² or higher, preferably 10⁵ atoms/cm² or higher. Zirconia or cerium oxide components each independently include over 50 wt % zirconia or cerium oxide, more preferably over 90 wt % zirconia or cerium oxide, and most preferably over 98 wt % zirconia or cerium oxide. Additionally, the zirconia or cerium oxide components preferably contains less than 1000 ppm, or more preferably less than 500 ppm, of impurities.

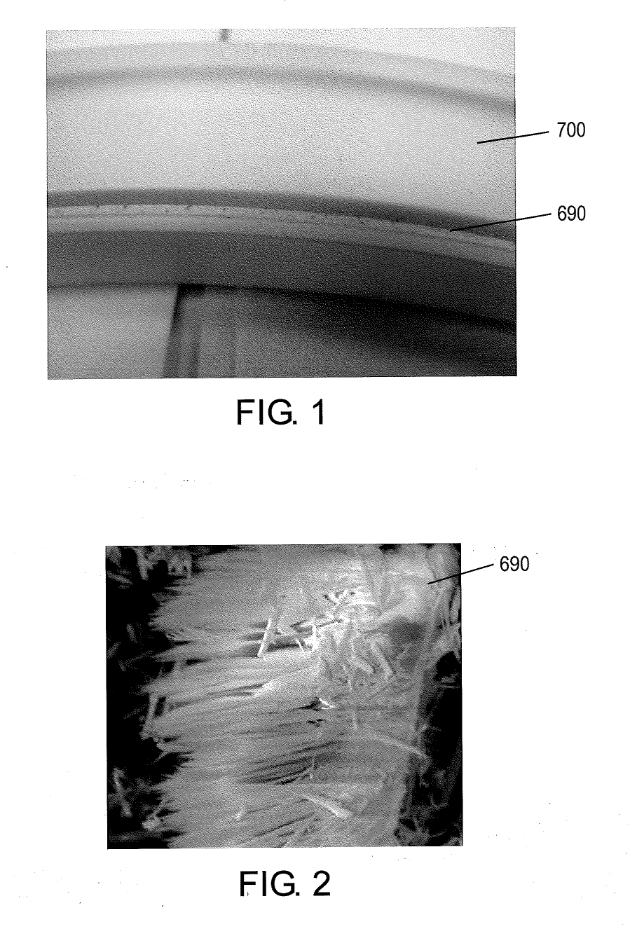

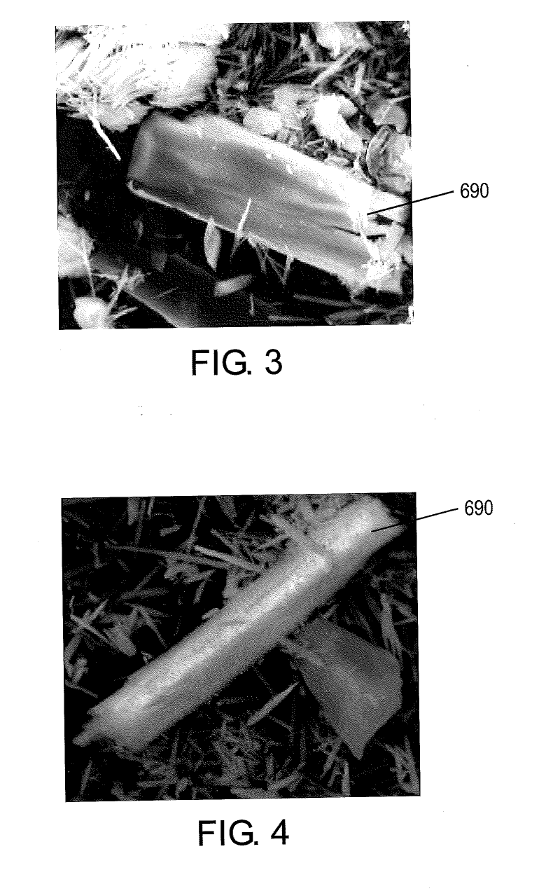

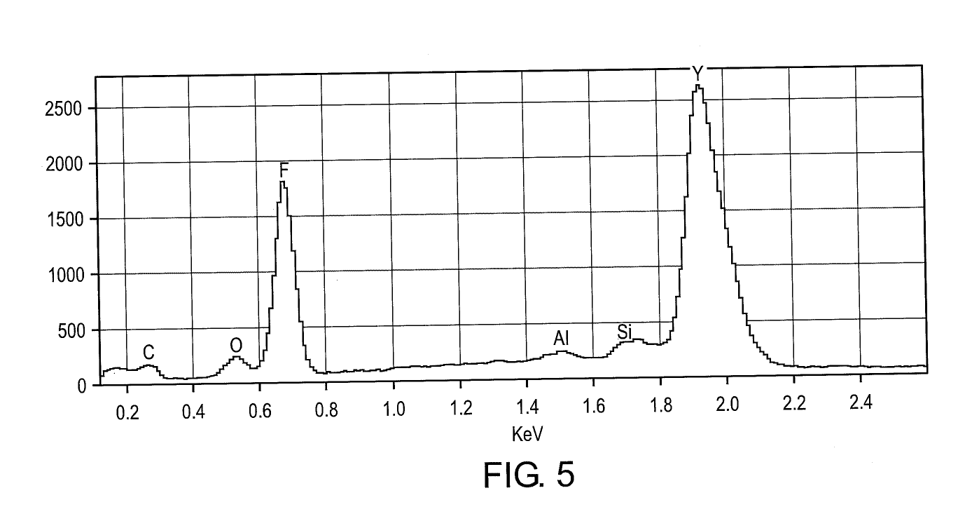

As shown in FIGS. 1-5, yttria edge rings having a surface roughness value (Rₐ) of about 64 microinches Rₐ, formed by successive material removal, after about 200 RF hours are still subject to high energy ion bombardment and are thus a source of potential micro-contamination. FIG. 1 is an illustration of a yttria edge ring entirely of yttria having a surface roughness value of about 64 microinches Rₐ after 200 RF hours of operation in a plasma etch chamber. FIGS. 2-4 show micrographs of the large particles left in the pocket of an yttria edge ring (shown in FIG. 1) having a surface roughness value of about 64 microinches Rₐ after about 200 RF hours. As shown in FIG. 5, an EDX chemical spectrum shows that the large particles consist of yttrium fluoride (YF₃) particles formed by conversion of the yttria during intense ion and chemical attack from the plasma. These particles are a considerable micro-contamination risk.

Thus, it is preferred that the surface roughness value of the components composed of yttria, zirconia and/or cerium oxide be considerably higher than 64 microinches Rₐ so that the edge ring lasts for at least about 500 RF hours, more preferably at least about 750 RF hours and most preferably at least about 1000 RF hours.

Thus, in a preferred embodiment, yttria components have a surface roughness value of greater than about 100 microinches (about 2.54 microns) Rₐ (e.g., greater than about 150 microinches Rₐ, greater than about 200 microinches Rₐ, greater than about 250 microinches Rₐ). More preferably, the yttria components have a surface roughness value of greater than about 300 microinches (about 7.62 microns) Rₐ (e.g., greater than about 350 microinches Rₐ, greater than about 400 microinches Rₐ, greater than about 450 microinches Rₐ). Accordingly, the yttria components having a rough surface can improve the adhesion of such polymer deposits on components, thereby reducing the occurrence of contamination by the polymer deposits.

Likewise, zirconia and/or cerium oxide components have a surface roughness value of greater than about 100 microinches (about 2.54 microns) Rₐ (e.g., greater than about 150 microinches Rₐ, greater than about 200 microinches Rₐ, greater than about 250 microinches Rₐ). More preferably, the zirconia and/or cerium oxide components have a surface roughness value of greater than about 300 microinches (about 7.62 microns) Rₐ (e.g., greater than about 350 microinches Rₐ, greater than about 400 microinches Rₐ, greater than about 450 microinches Rₐ). Accordingly, the zirconia and/or cerium oxide components having a rough surface can improve the adhesion of such polymer deposits on components, thereby reducing the occurrence of contamination by the polymer deposits.

In the following detailed description, reference is made to the accompanying drawings, which form a part of this application. The drawings show, by way of illustration, specific embodiments in which the invention may be practiced. It is to be understood that other embodiments may be utilized and structural changes may be made without departing from the scope of the present invention.

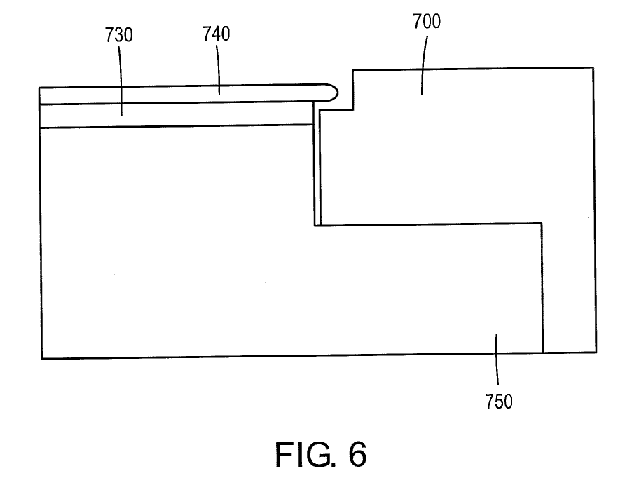

As described herein, an edge ring is formed of yttria, zirconia and/or cerium oxide having a rough surface by successive material removal. In a preferred embodiment, the edge ring 700 is made of yttria, as shown in FIG. 6. The edge ring 700 may be made in any shape, preferably a symmetrical shape, in order to provide a more uniform ground for the plasma in the plasma etch chamber. Preferably, the edge ring 700 is formed of solid yttria, zirconia and/or cerium oxide.

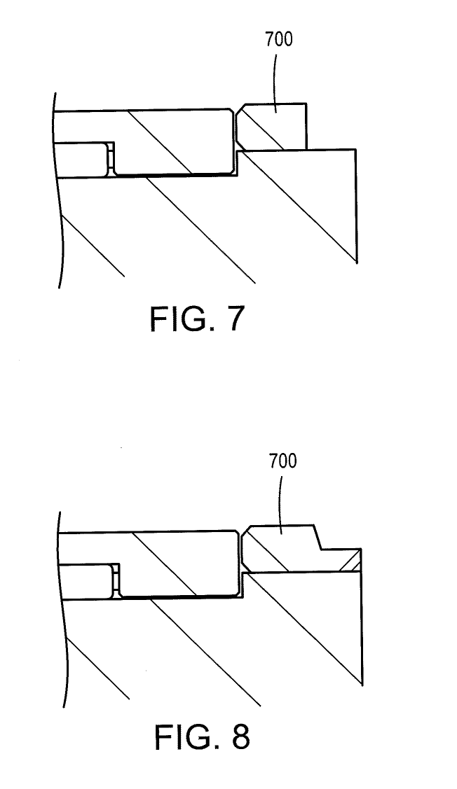

As illustrated in FIG. 7, an edge ring 700 with a rectangular cross-section may be used. However, the edge ring 700 can have any desired configuration. As shown in FIG. 8, the edge ring 700 can include one flange (or more), where the orientation of the one or more flanges, as well as the length and width of the edge ring may be provided.

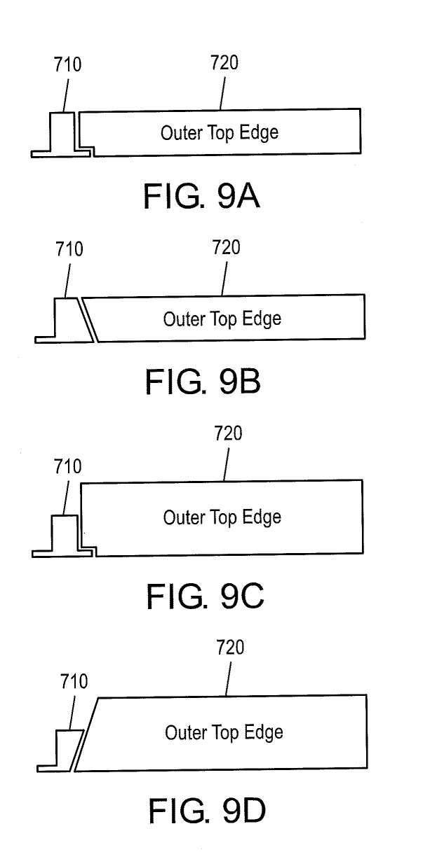

As shown in FIGS. 9A to 9D, in an embodiment, the top edge ring 700 may be a multi-part ring, e.g., at least two pieces. Such a design, for example, would allow for replacement of the inner piece 710, were it to need replacing, without the need for replacing the outer piece 720. The outer piece 720 typically does not degrade as quickly as the inner piece 710 because the inner piece 710 may be more exposed to the plasma than the outer piece 720. Use of a yttria, zirconia and/or cerium oxide edge ring comprising at least two pieces, as described herein, could therefore result in additional cost savings both due to the ability to replace independent pieces of the ring and due to the longer lifetime of the part.

The edge ring 700 preferably has a symmetrical shape, such as a circular ring, an oblong ring, a rectangular ring, etc. Preferably, the solid edge ring having a rough surface 700 is about 0.1 to about 0.6 inches thick (e.g., about 0.1 to about 0.2 inches thick, about 0.2 to about 0.3 inches thick, about 0.3 to about 0.4 inches thick, about 0.4 to about 0.5 inches thick or about 0.5 to about 0.6 inches thick). In a preferred embodiment, the solid edge ring having a rough surface is about 0.1 to about 0.6 inches wide (e.g., about 0.1 to about 0.2 inches thick, about 0.2 to about 0.3 inches thick, about 0.3 to about 0.4 inches thick, about 0.4 to about 0.5 inches thick or about 0.5 to about 0.6 inches thick).

In a preferred embodiment, as shown in FIG. 6, the diameter of electrostatic chuck (ESC) wafer contact surface 730 is smaller than the wafer 740 diameter by about 1 mm to about 2 mm to prevent attack of ESC materials during etching. Thus, the wafer 740 overhangs the edge ring 700. The top of the edge ring 700 is positioned as closely as possible to the underside of the wafer.

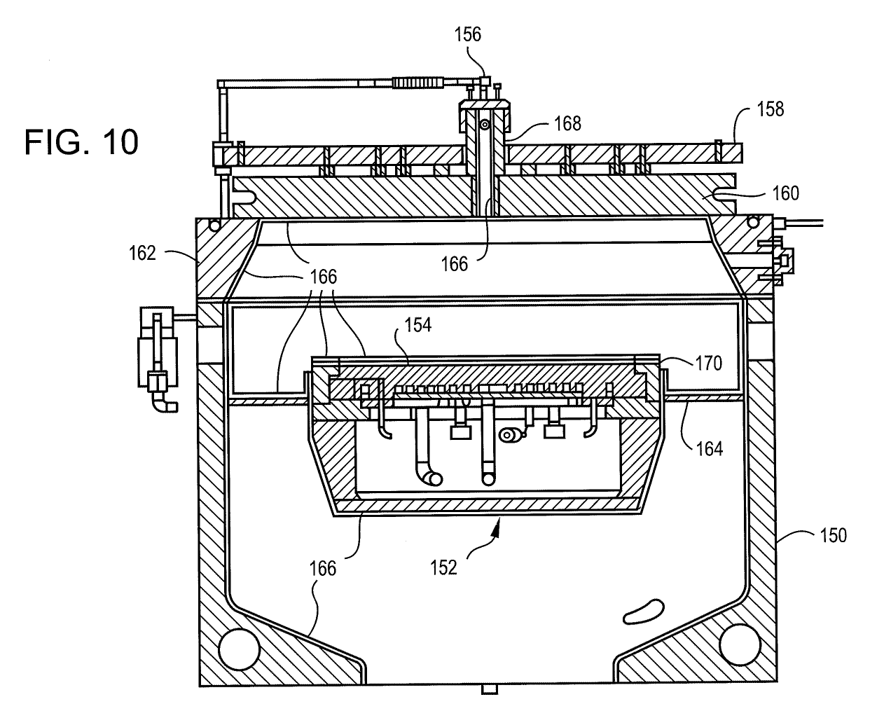

FIG. 10 shows selected internal surfaces of reactor components, such as the annular member 162, dielectric window 160, substrate support 152, chamber liner 164, gas injector 168, focus ring 170 and the electrostatic chuck 154 formed of yttria, zirconia or cerium oxide as described herein. Other components in FIG. 10 include gas feed 156, chamber 150, and inductive coil 158. Components may receive a ceramic coating 166.

The yttria, zirconia or cerium oxide components may be used in any plasma chamber wherein plasma is generated by capacitive coupling, inductive coupling, microwave, magnetron or other technique. The yttria, zirconia or cerium oxide components may be used as original equipment in a plasma chamber, or as a replacement in another plasma chamber. Besides etching, the yttria, zirconia or cerium oxide components may be used in chambers for plasma PVD, CVD, ion implantation, etc.

As compared to coated components, such as an edge ring having a yttria coating, the solid yttria, zirconia or cerium oxide components having a mechanically or chemically roughened surface, as described herein, have a longer life. This is due to the fact that the yttria coating on edge rings can fail if the coating does not sufficiently grip the underlying layer. Additionally, the coating can wear through, which is not a problem with solid yttria, zirconia or cerium oxide components having a rough surface.

Sections of a ring of 99.9% solid yttria were tested under various etching conditions The sections had an inner chord of about 1.15 inches (about 2.92 cm), surface area of about 26.1 cm², and volume of about 10.8 cm³. The sections were etched using H₂SO₄, HCl, and HNO₃ at various concentrations and temperatures. Surface roughness produced by etching was found to be approximately linearly related to exposure time and acid concentration. A surface roughness of 200 μ-in Rₐ was obtained both by 6 hours exposure of 10 wt % H₂SO₄ at 50° C. and by 48 hours exposure of 20 wt % H₂SO₄ at room temperature. Among the three acids tested, H₂SO₄ etched the most quickly, followed by HCl, and then HNO₃. Preferred etching conditions (i.e., those producing a surface roughness of about 200 microinches, or about 5 microns, Rₐ) were 10 wt % H₂SO₄ at 50° C. for 6 hours; 20 wt % H₂SO₄ at 20° C. for 48 hours; 10 wt % HCl at 50° C. for 6-8 hours; and 10 wt % HNO₃ at 50° C. for 7 hours. The etched surface was examined under scanning electron microscopy and was observed to be highly porous without loose particles, making it ideal for capturing plasma chamber deposition. The etching increased the effective surface area dramatically, which should improve the effective life span of a component.

In this specification, the word “about” is often used in connection with numerical values to indicate that mathematical precision of such values is not intended. Accordingly, it is intended that where “about” is used with a numerical value, a tolerance of 10% is contemplated for that numerical value.

All of the above-mentioned references are herein incorporated by reference in their entirety to the same extent as if each individual reference was specifically and individually indicated to be incorporated herein by reference in its entirety.

It will be appreciated by those skilled in the art that additions, deletions, modifications, and substitutions not specifically described herein may be made without departing from the spirit and scope of the appended claims.

What is claimed is:

1. A component for use in a plasma chamber comprising:
a component entirely of a ceramic material, the component having a surface roughness value of at least about 100 microinches (about 2.54 microns) Rₐ produced by mechanical roughening and acid etching.

2. The component of claim 1, wherein the ceramic material is selected from the group consisting of yttrium oxide, zirconium oxide, cerium oxide and combinations thereof.

3. The component of claim 1, wherein the component:
(a) is a gas injector, a confinement ring, an upper electrode, an insulator ring and/or an edge ring;
(b) comprises at least 50 wt % yttria, zirconia or cerium oxide, at least 90 wt % yttria, zirconia or cerium oxide, at least 98 wt % yttria, zirconia or cerium oxide or at least 99.9 wt % yttria, zirconia or cerium oxide;
(c) has a density greater than 4.5 g/cm³ or greater than 4.75 g/cm³, and wherein the ceramic material is yttria;
(d) is a consumable part having a lifetime of at least about 500 RF hours, at least about 750 RF hours or at least about 1000 RF hours of operation of the plasma chamber;
(e) is entirely of yttria with less than 100 ppm of each of silicon, aluminum, calcium, iron, and zirconium or less than a total of 500 ppm of silicon, aluminum, calcium, iron, and zirconium;
(f) has a surface roughness value of at least about 300 microinches (about 7.62 microns) Rₐ; or
(g) two or more of (a) through (f).

4. The component of claim 3, wherein the component is the edge ring and is:
(a) about 0.1 to about 0.6 inches thick and about 0.1 to about 0.6 inches wide;
(b) a single-piece edge ring or a multi-part edge ring; or
(c) both (a) and (b).

5. A method of forming the component of claim 1 via successive material removal comprising:
forming a component entirely from yttria, zirconia, and/or cerium oxide;
exposing the component to one or more of percussive blasting and surface grinding to form a roughened exposed surface on the component; and
etching the roughened surface with a wet chemical etchant to remove loose fractured material and form a component having an etched surface,
wherein the etched surface has a surface roughness value or at least about 100 microinches (about 2.54 microns) Rₐ.

6. The method of claim 5, wherein:
(a) the surface roughness value is at least about 300 microinches (about 7.62 microns) Rₐ;
(b) wherein the wet chemical etchant comprises at least one mineral acid;
(c) wherein the etching removes attached particles of yttria, zirconia and/or cerium oxide so as to inhibit micro-contamination of substrates during processing.

7. The method of claim 5, wherein the exposing comprises:
(a) said percussive blasting, and said percussive blasting comprises bead blasting or grit blasting;
(b) said surface grinding, and said surface grinding comprises grinding the component with a coarse media or a slurry comprising a material selected from the group consisting of aluminum oxide, silicon carbide, cerium oxide, zirconium oxide, diamond and combinations thereof; or
(c) both (a) and (b).

8. The method of claim 5, wherein the wet chemical etchant comprises at least one mineral acid selected from the group consisting of HCl, H₂SO₄, HNO₃ and combinations thereof.

9. The method of claim 5, wherein component is formed by molding yttria powder into a molded shape in a mold optionally followed by hot pressing, and sintering the molded shape.

10. A plasma processing apparatus, comprising the component of claim 1.

11. The plasma processing apparatus of claim 10, wherein said plasma processing apparatus comprises a plasma etching apparatus.

12. A method of forming a component with an etched surface, comprising:
etching with hydrochloric acid the surface of a sintered component formed entirely of yttria to create an etched surface,
wherein the etched surface has a surface roughness value of at least about 100 microinches (about 2.54 microns) Rₐ.

13. The method of claim 12, wherein the surface roughness value is at least about 300 microinches (about 7.62 microns) Rₐ.

14. The method of claim 12, wherein:
(a) the etching is conducted at or below about 50° C.;
(b) the hydrochloric acid is at a concentration of from about 5% to about 25%; or
(c) both (a) and (b).

15. The method of claim 12, further comprising the steps of forming the sintered component and exposing the component to one or more of percussive blasting and surface grinding to form a roughened exposed surface on the component prior to said etching.

16. The method of claim 12, wherein the etching is conducted within a time period of between about 6 and 24 hours with a hydrochloric acid concentration of from about 5% to about 15% and a temperature of between about room temperature and about 50° C.

17. The method of claim 12, wherein the etching removes attached particles of yttria so as to inhibit micro-contamination of substrates during processing.

18. The method of claim 12, wherein said component:
(a) is a gas injector, a confinement ring, an upper electrode, an insulator ring and/or an edge ring;
(b) has a density greater than 4.5 g/cm³ or greater than 4.75 g/cm³;
(c) is a consumable part having a lifetime of at least about 500 RF hours, at least about 750 RF hours or at least about 1000 RF hours of operation of the plasma chamber;
(d) has less than 100 ppm of each of silicon, aluminum, calcium, iron, and zirconium or less than a total of 500 ppm of silicon, aluminum, calcium, iron, and zirconium; or
(e) two or more of (a) through (d).

19. The method of claim 12, wherein the component is the edge ring and is:
(a) about 0.1 to about 0.6 inches thick and about 0.1 to about 0.6 inches wide;
(b) a single-piece edge ring or a multi-part edge ring; or
(c) both (a) and (b).

20. A component formed by the method of claim 12.
